(19) United States
(12) Patent Application Publication
(10) Pub. No.: US 2025/0323013 A1
(43) Pub. Date: Oct. 16, 2025

(54) Detection of Space Charge Effect During Ion Implantation

(71) Applicant: Applied Materials, Inc., Santa Clara, CA (US)

(72) Inventors: Chien-Lun Lai, Taoyuan (TW); Tzu-Ping Chu, Hsinchu (TW); Hsin-Hsiang Fang, Taoyuan (TW); Chen-Hsiang Lin, Taoyuan (TW); Chia-Ling Chan, Leuven (BE); Chung-Hsiung Chen, Taoyuan (TW); Tsung-Liang Chen, South Hamilton, MA (US); Julian Duchaine, Froges (FR)

(21) Appl. No.: 18/633,764

(22) Filed: Apr. 12, 2024

(51) Int. Cl. H01J 37/244; H01J 37/147; H01J 37/317

(52) U.S. Cl. CPC H01J 37/244; H01J 37/1474; H01J 37/3171; H01J 2237/24564; H01J 2237/24578; H01J 2237/30433

(57) ABSTRACT

A system and method to measure beam height during an ion implant process is disclosed. The ion implanter includes one or more current sensors located in the process chamber behind the platen. In this way, each time the platen is scanned, the one or more current sensors measure beam current. This measured beam current and the scan position of the platen associated with each measurement may be used to calculate the height of the ion beam. In some embodiments, for improved accuracy, the slope of the measured beam current with respect to scan position is used to determine the beam height. Immediate detection of beam height may be used to minimize the number of workpieces that are misprocessed.

### FIELD

This disclosure describes systems and methods to detect space charge effect while ion implantation is being performed.

### BACKGROUND

Semiconductor devices are fabricated using a plurality of processes, some of which implant ions into the workpiece. The incoming ion beam typically is very narrow in the height direction, but has a width that is greater than the diameter of the workpiece. This width may be achieved using a ribbon ion beam, or by the scanning of a spot ion beam.

Many factors affect the height of the ion beam in the process chamber. For example, beam current, beam energy, beam focus and other parameters of the ion implanter affect the height of the ion beam. Additionally, a plasma flood gun (PFG) in the process chamber may be used to inject low energy electrons into the ion beam. These electrons may help reduce “beam blowup”, in which the ion beam expands spatially in the process chamber due to the repulsion of positively charged ions from one another. Defective operation of the PFG may contribute to excess beam height. Further, in addition to improper settings or defective hardware, there may be other causes of beam blowup.

To ensure proper ion beam characteristics during an ion implantation operation, a calibration process may be performed to measure the height, beam current and other profile, characteristics of the ion beam. This is typically performed when the ion implanter is being configured for a new recipe, wherein a recipe includes the species to be ionized, the beam current to be used, and other parameters. However, after this calibration process is completed, the parameters of the ion beam are typically not checked again until the next time the system is reconfigured for a different recipe or a preventative maintenance is performed.

However, beam degradation may occur between these calibration processes and may go undetected until the ion implanter is configured for the next recipe, resulting in misprocessing of semiconductor device workpieces.

Therefore, it would be beneficial if there were a system and method to monitor the ion beam during ion implantation, such that potential issues, such as beam blowup, are detected quickly. This results in quicker diagnosis of issues, which in turn may result in higher device yield.

### SUMMARY

A system and method to measure beam height during an ion implant process is disclosed. The ion implanter includes one or more current sensors located in the process chamber behind the platen. In this way, as the platen is scanned, the one or more current sensors may measure the beam current. This measured beam current and the scan position of the platen associated with each measurement may be used to calculate the height of the ion beam. In some embodiments, for improved accuracy, the slope of the measured beam current with respect to scan position is used to determine the beam height. Immediate detection of beam height may be used to minimize the number of workpieces that are misprocessed.

According to one embodiment, a method of determining a height of an ion beam while the ion beam is being used to implant a workpiece is disclosed. The method comprises directing the ion beam toward the workpiece; scanning the workpiece in a first direction such that an entirety of the workpiece is implanted by the ion beam; measuring a beam current as a function of scan position, using one or more current sensors disposed in a path of the ion beam, downstream from the workpiece as the workpiece is implanted by the ion beam; determining a slope of the beam current with respect to scan position in the first direction; and calculating the height of the ion beam based on the slope of the beam current. In some embodiments, the beam current is measured and the height of the ion beam is calculated each time the workpiece is scanned in the first direction. In some embodiments, the method also comprises alerting an operator if an issue is detected, wherein an issue is detected when the height of the ion beam, as calculated, differs from an expected height. In some embodiments, the method also comprises automatically stopping an implant process if an issue is detected, wherein an issue is detected when the height of the ion beam, as calculated, differs from an expected height. In certain embodiments, the ion beam is generated by an ion implanter, and the method also comprises automatically initiating a calibration process of the ion implanter after the implant process has been stopped to attempt to correct the issue. In some embodiments, the method also comprises alerting an operator if the height of the ion beam, as calculated, differs from an expected height by a first predetermined amount; and automatically stopping an implant process if the height of the ion beam, as calculated, differs from the expected height by a second predetermined amount, greater than the first predetermined amount. In some embodiments, the method also comprises alerting an operator if a ratio of the height of the ion beam, as calculated, to an expected height is outside a first acceptable range; and automatically stopping an implant process if the ratio is outside a second acceptable range, greater than the first acceptable range.

According to another embodiment, an ion implanter is disclosed. The ion implanter comprises an ion source to generate an ion beam; a process chamber, comprising: a platen configured to move in a first direction such that an entirety of a workpiece disposed on the platen is implanted by the ion beam; and one or more current sensors in a path of the ion beam downstream from the platen to measure beam current; one or more beamline components to direct the ion beam toward the process chamber; and a controller, to receive beam current measurements from the one or more current sensors and an associated scan position for each beam current measurement, wherein the controller is configured to calculate a height of the ion beam based on the beam current measurements and the associated scan positions. In some embodiments, the beam current is measured and the height of the ion beam is calculated each time the workpiece is scanned in the first direction. In some embodiments, the controller calculates a slope of the beam current as a function of scan position, and uses the slope to calculate the height of the ion beam. In some embodiments, the controller alerts an operator if an issue is detected, wherein an issue is detected when the height of the ion beam, as calculated, differs from an expected height. In some embodiments, the controller automatically stops an implant process if an issue is detected, wherein an issue is detected when the height of the ion beam, as calculated, differs from an expected height. In some embodiments, the controller alerts an operator if the height of the ion beam, as calculated, differs from an expected height by a first predetermined amount; and automatically stops an implant process if the height of the ion beam, as calculated, differs from the expected height by a second predetermined amount, greater than the first predetermined amount. In some embodiments, the controller alerts an operator if a ratio of the height of the ion beam, as calculated, to an expected height is outside a first acceptable range; and automatically stops an implant process if the ratio is outside a second acceptable range, greater than the first acceptable range.

According to another embodiment, a method of monitoring and controlling an operation of an ion implanter is disclosed. The method comprises using the ion implanter to measure a beam current of an ion beam being directed toward a workpiece as a function of scan position as the workpiece is being implanted and scanned in a scanning direction; transmitting data from the ion implanter to a remote monitoring system; and using the data to provide an appropriate corrective action from the remote monitoring system to the ion implanter. In some embodiments, the data transmitted from the ion implanter comprises measurements of beam current as a function 41 position; e remote monitoring system calculates beam height from the data. In some embodiments, the remote monitoring system generates historical beam height trending from the beam height calculated from the data. In some embodiments, the remote monitoring system also receives information regarding corrective actions that have previously been performed on the ion implanter. In certain embodiments, the remote monitoring system predicts future beam height changes and provides an appropriate corrective action. In certain embodiments, the remote monitoring system uses machine learning or artificial intelligence systems to provide the appropriate corrective action.

### BRIEF DESCRIPTION OF THE DRAWINGS

For a better understanding of the present disclosure, reference is made to the accompanying drawings, in which like elements are referenced with like numerals, and in which:

FIG. 1 is a block diagram of an ion implanter that detects ion beam blowup according to one embodiment;

FIG. 2 is a block diagram of a process chamber that includes a current sensor;

FIGS. 3A-3H show the relationship between the ion beam, the current sensors and the platen during implantation;

FIG. 4A shows the relationship between beam current and scan position for two different ion beams;

FIG. 4B shows the relationship between the slope of the beam current and the scan position for the ion beams of FIG. 4A; and

FIG. 5 shows a plurality of ion implanters in communication with a remote monitoring system.

### DETAILED DESCRIPTION

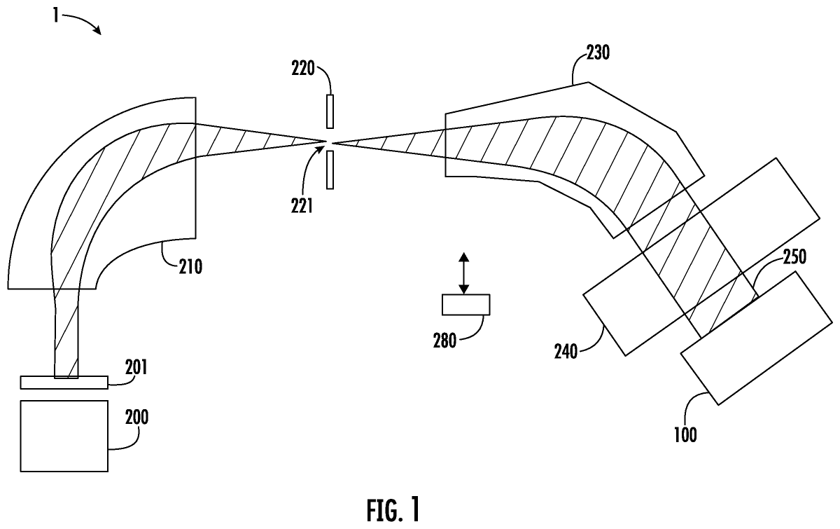

FIG. 1 shows an ion implanter 1 that detects ion beam blowup according to one embodiment. An ion source 200 is used to generate an ion beam 250. The ion source 200 may be an indirectly heated cathode (IHC) ion source. Alternatively, the ion source 200 may be a capacitively coupled plasma source, an inductively coupled plasma source, a Bernas source or another source. Thus, the type of ion source is not limited by this disclosure. Disposed outside and proximate the extraction aperture of the ion source 200 is the extraction optics 201, which may comprise one or more electrodes.

Located downstream from the extraction optics 201 is a mass analyzer 210. The mass analyzer 210 uses magnetic fields to guide the path of the extracted ion beam. The magnetic fields affect the flight path of ions according to their mass and charge. A mass resolving device 220 that has a resolving aperture 221 is disposed at the output, or distal end, of the mass analyzer 210. By proper selection of the magnetic fields, only those ions in the ion beam 250 that have a selected mass and charge will be directed through the resolving aperture 221. Other ions will strike the mass resolving device 220 or a wall of the mass analyzer 210 and will not travel any further in the system.

A collimator 230 may be disposed downstream from the mass resolving device 220. The collimator 230 accepts the ions from the ion beam 250 that pass through the resolving aperture 221 and creates an ion beam formed of a plurality of parallel or nearly parallel beamlets. The output, or distal end, of the mass analyzer 210 and the input, or proximal end, of the collimator 230 may be a fixed distance apart. The mass resolving device 220 is disposed in the space between these two components.

Located downstream from the collimator 230 may be an acceleration/deceleration stage 240. The acceleration/deceleration stage 240 is a beam-line lens component configured to independently control deflection, deceleration, and focus of the ion beam. For example, the acceleration/deceleration stage 240 may be an electrostatic filter (EF). The acceleration/deceleration stage 240 may contain components, such as electrodes or rods, which may be negatively biased. The ion beam 250 that exits the acceleration/deceleration stage 240 enters the process chamber 100.

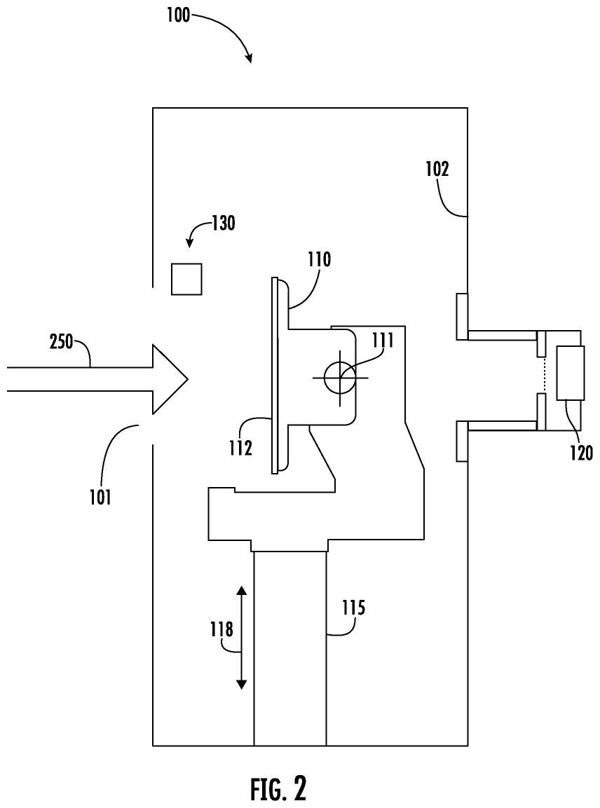

As best seen in FIG. 2, the process chamber 100 includes a platen 110, on which a workpiece 112 may be disposed. When in the operational position, the ion beam 250 impacts the workpiece 112. A plasma flood gun 130 is disposed near the entrance 101 to the process chamber 100. In addition, one or more current sensors 120 are disposed at the back wall 102 of the process chamber 100. The current sensors 120 have a height that is greater than the height of the ion beam 250. For example, in certain embodiments, the nominal height of the ion beam 250 may be about 90 mm, while the height of the current sensors 120 may be greater than 100 mm.

A controller 280 may be in communication with one or more power supplies such that the voltage or current supplied by these power supplies may be monitored and/or modified. The controller 280 may also be in communication with the one or more current sensors 120. The controller 280 may include a processing unit, such as a microcontroller, a personal computer, a special purpose controller, or another suitable processing unit. The controller 280 may also include a non-transitory storage element, such as a semiconductor memory, a magnetic memory, or another suitable memory. This non-transitory storage element may contain instructions and other data that allows the controller 280 to perform the functions described herein.

In certain embodiments, the ion source 200 may generate a ribbon beam that travels through these components. Of course, other ion implanters may be utilized. For example, the ion implanter may generate a scanned ion beam rather than a ribbon ion beam. Such an ion implanter includes an ion source that creates a spot beam. This type of ion implanter also includes a mass analyzer and a mass resolving device, as described above. In addition, a scanner, which may be electrostatic or another type is used to create a scanned ion beam. The scanned ion beam may pass through an angle corrector. The angle corrector is designed to deflect ions in the scanned ion beam to produce an ion beam having parallel ion trajectories, thus focusing the scanned ion beam. Specifically, the angle corrector is used to alter the diverging ion trajectory paths into substantially parallel paths of the ion beam 250. In some embodiments, the angle corrector may comprise magnetic pole pieces which are spaced apart to define a gap and a magnet coil which is coupled to a power supply. The scanned ion beam passes through the gap between the magnetic pole pieces and is deflected in accordance with the magnetic field in the gap. In other embodiments, the angle corrector may be an electrostatic lens sometimes referred to as a parallelizing lens.

FIG. 2 shows the process chamber 100 of FIG. 1 in more detail. The ion beam 250 enters the process chamber 100 through an entrance 101. The process chamber 100 includes one or more current sensors 120 located at the back wall 102. A platen 110 is also disposed in the process chamber 100 to hold the workpiece 112. The platen 110 may be an electrostatic platen that is used to clamp and hold the workpiece 112 while the ion beam 250 is directed into the process chamber 100. In some embodiments, the platen 110 may be elevated and lowered in a Y direction 118 through the movement of shaft 115. Additionally, the platen 110 may rotate about X axis 111. In certain embodiments, the platen 110 may be rotated 90° so that the clamping surface of the platen 110 is horizontal, allowing a workpiece 112 to be placed on the platen 110. The platen 110 is then rotated into the operational, or implant position, which is shown in FIG. 2.

A plasma flood gun 130 is disposed near the entrance 101 of the process chamber 100. The plasma flood gun 130 includes at least one plasma chamber that is used to generate a plasma. In some embodiments, an inert gas, such as xenon, may be introduced into the plasma chamber of the plasma flood gun 130. Low energy electrons and positive ions exit the plasma chamber of the plasma flood gun 130 through one or more apertures and enter the process chamber 100.

Since the height of the ion beam 250 is much smaller than the size of the workpiece, to implant the workpiece 112 with ions from the ion beam 250, the platen 110 is raised and lowered in the Y direction 118 by actuation of the shaft 115. This allows an entirety of the workpiece 112 to be exposed to the ion beam 250.

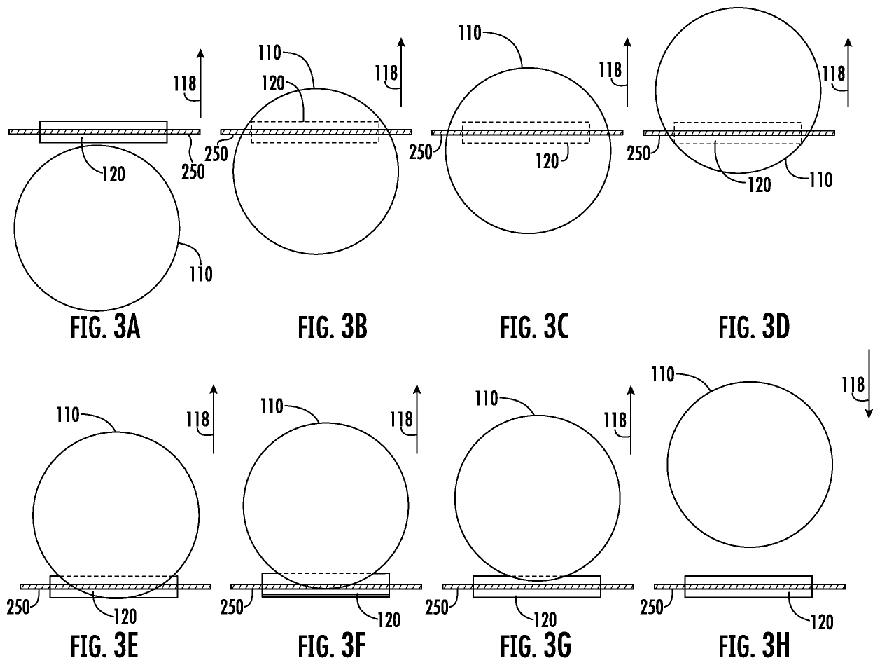

In this present system, the controller 280 receives data from the current sensors 120 as the ion implantation process is being performed. Specifically, as platen 110 is raised and lowered in the Y direction 118, the current sensed by the one or more current sensors 120 is being monitored and provided to the controller 280. FIGS. 3A-3H show the relationship between the ion beam 250, the one or more current sensors 120 and the platen 110 as the platen is raised in the Y direction 118. While FIGS. 3A-3H show the platen 110 as being round, it is understood that the platen may be other shapes. The platen 110 moves from a first position, where the platen is below the ion beam 250 (see FIG. 3A) and is not impacted by the ion beam 250, to a second position, where the platen is above the ion beam 250 and is not impacted by the ion beam 250 (see FIG. 3H). FIGS. 3A-3H show the path of the platen 110 as it moves from the first position to the second position. Specifically, the platen 110 starts in the first position, shown in FIG. 3A. As shown in FIGS. 3B-3D, as the platen 110 is moved upward, the entirety of the ion beam 250 is blocked by the platen 110 and does not strike the one or more current sensors 120. In FIG. 3E, a small portion of the ion beam 250 impacts the one or more current sensors 120. The amount of the ion beam 250 that impacts the one or more current sensors 120 increases as the platen 110 continues moving upward in the Y direction 118, as shown in FIGS. 3E-3G. Once the platen 110 completely clears the ion beam 250, the direction of motion of the platen 110 is reversed, as shown in FIG. 3H.

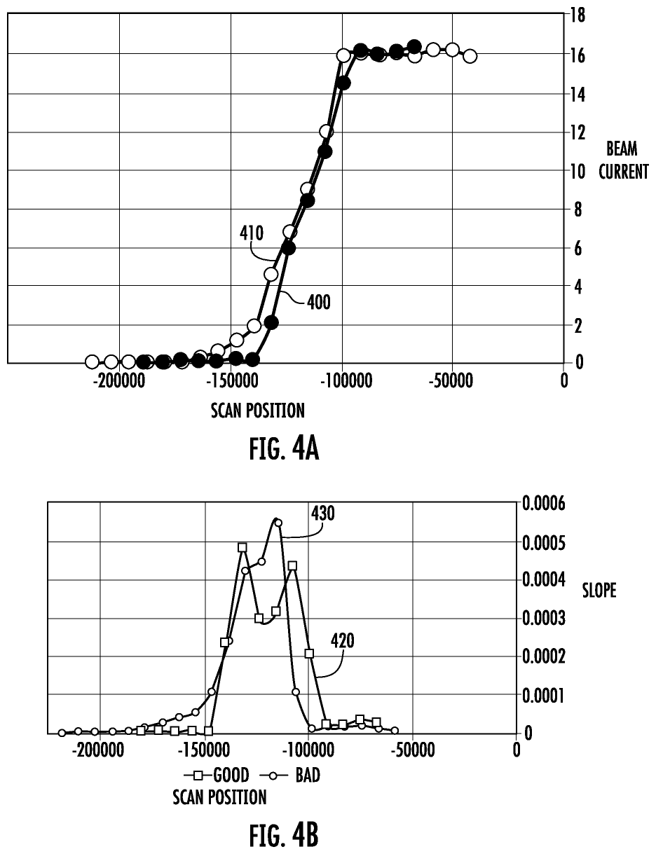

FIG. 4A shows representative graphs of beam current as measured by the one or more current sensors 120 as a function of scan position of the platen. Line 400 shows the beam current as a function of scan position for a known good ion beam. Note that the difference in scan position between the beam current transitioning from no current to maximum current represents the height of the ion beam 250 in the Y direction 118. Line 410 shows the beam current as a function of scan position for an ion beam experiencing beam blowup. Again, the difference in scan position between the beam current transitioning from no current to maximum current again represents the height of the ion beam 250 in the Y direction 118.

Note that, in certain embodiments, determining the exact start and end of the transition zone of the ion beam current may be problematic. Thus, in certain embodiments, the controller 280 (or another controller) uses the data from FIG. 4A to generate graphs showing the absolute value of the slope of the beam current as a function of scan position. As shown in FIG. 4B, line 420 represents the absolute value of the slope of line 400 as a function of scan position; while line 430 represents the same for line 410.

The slope may be defined as the difference in beam current between two successive measurements, divided by the difference in scan position of those two successive measurements. Stated differently, the slope at the present measurement is defined as the beam current at the next measurement, less beam current at the present measurement, divided by the difference in scan position between the next measurement and the present measurement, or:

$$slope ( x ) = \frac{Beam Current ( x + 1 ) - Beam Current ( x )}{Scan Position ( x + 1 ) - Scan Position ( x )}$$

where beam current may be measured in milliamps and scan position may be measured in micrometers. Alternatively, this may be defined as:

$$slope ( x ) = \frac{Beam Current ( x ) - Beam Current ( x - 1 )}{Scan Position ( x + 1 ) - Scan Position ( x - 1 )}$$

Next, as noted above, the absolute value of these slopes are calculated and displayed in FIG. 4B as a function of scan position.

To calculate the beam height in the Y-direction, a first threshold may be established. In some embodiments, this first threshold may be 0. Of course, other values may be used. Any slope value greater than that first threshold is considered to be within the transition zone. If the first slope value that has a value greater than the first threshold is defined as X1, and the last slope value having a value greater than the first threshold is defined as X2, then the beam height may be defined as the scan position at X2, less the scan position at X1.

In another embodiment, the beam current at each scan position is saved and X1 and X2 are defined as the first and last scan positions that had a beam current that was at least some percentage of the peak value of the beam current, such as 1%.

Note that a beam height measurement may be performed each time the platen 110 moves from the first position to the second position, or from the second position back to the first position. Thus, each pass of the platen through the ion beam 250 allows the measurement of the beam height. In this way, beam height measurements may be made continuously during the ion implantation process.

This measured beam height may be used in a plurality of ways.

In a first embodiment, the measured beam height may be used locally, such as by the controller 280. This measured beam height, represented as X2-X1, may be compared to the expected beam height. If the measured beam height differs from the expected beam height by more than a predetermined amount, this may be indicative of an issue. In some embodiments, the ratio of measured beam height to expected beam height is used to set a threshold. For example, an issue may be indicated if the ratio is outside a first acceptable range, such as between 0.7 and 1.3. Alternatively, the difference between the measured beam height and the expected beam height may be used to set the threshold. In this embodiment, if the absolute value of this difference is more than a first predetermined threshold, such as 15 mm, this may be indicative of an issue. Of course, different recipes may have different behavior and the first acceptable range and the first predetermined threshold may depend on data collection and device sensitivity.

If the controller 280 detects an issue, it may take some corrective action. In some embodiments, this action may be to provide an alert or other indication to the operator that the measured beam height may be outside recommended parameters. In response, the operator may choose to stop the implantation process and perform a calibration process to determine if a recalibration of the components will rectify the issue. Alternatively or additionally, the operator may choose to perform a diagnostic check of the components in the beam line, including the plasma flood gun 130. In this way, it is possible that yield is minimally impacted, as the issue was raised immediately. Thus, it is possible that only one workpiece was misprocessed.

In certain embodiments, the controller 280 may also establish a second acceptable range or a second predetermined threshold, greater than the first acceptable range and the first predetermined threshold respectively. For example, the second acceptable range may be 0.6 to 1.4 and the second predetermined threshold may be 20 mm. Of course, different recipes may have different behavior and the second acceptable range and the second predetermined threshold may depend on data collection and device sensitivity. In the event that the measured beam height is outside the second acceptable range or the second predetermined threshold, the controller 280 may perform more drastic actions, such as automatically stopping the ion implantation process. This may be invoked in the event of a sudden large deviation in the beam height, or a more gradual deviation that was not addressed by the operator.

In yet other embodiments, when the first acceptable range or first threshold is reached, the controller 280 may choose to stop the ion implantation process and initiate a calibration process automatically. In this embodiment, the real time beam height measurement technique, described above, may be used to aid in the calibration process. In this event, the workpiece currently being processed may be discarded, however, any workpieces that are subsequently processed are properly processed.

Note that these thresholds and acceptable ranges are exemplary. In some embodiments, these limits may be derived empirically, based on past performance of the ion implanter. In other embodiments, predetermined values may be used.

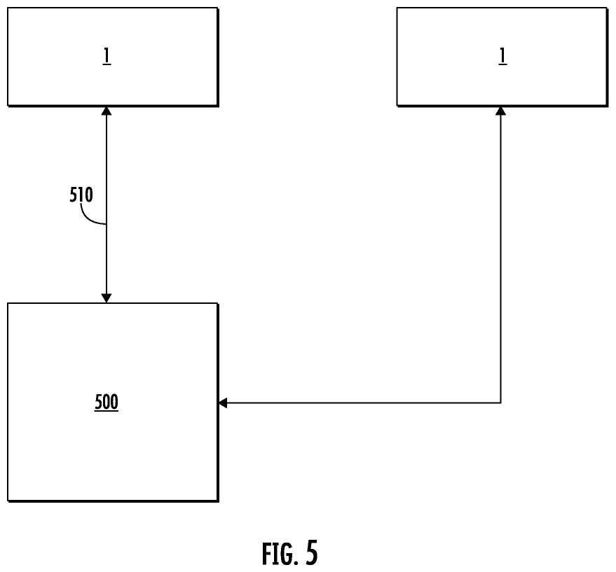

In another embodiment, shown in FIG. 5, the ion implanter 1 may be in communication with a remote monitoring system 500, which may include a data server. This may be achieved using a traditional network connection 510. Further, the remote monitoring system 500 may also be in communication with a plurality of other ion implanters. In this embodiment, the controllers 280 from each ion implanter 1 forward the real time beam measurements to the remote monitoring system 500. These beam measurements may include beam current measurements from the current sensors, which may be translated into beam height information by the remote monitoring system 500. Alternatively, the controller 280 may forward calculated beam height measurements to the remote monitoring system 500. Thus, the remote monitoring system 500 may receive a large amount of data which results in the historic beam height trending for each ion implanter. Furthermore, the remote monitoring system 500 may also include means that support personnel may use to provide other types of input to the remote monitoring system 500 that are associated with a particular ion implanter. As an example, in addition to providing the measured beam height information, the remote monitoring system 500 may also receive information regarding corrective actions that were taken on that ion implanter 1 to address any issues. In this way, the remote monitoring system 500 may use machine learning or artificial intelligent systems to predict upcoming beam height changes and to notify users of the corrective action that is most appropriate for a particular ion implanter based on its measured beam height data, as well as previously collected corrective actions.

The present system and method have many advantages. Plasma flood guns are useful in reducing beam blowup in the process chamber. The present disclosure allows immediate detection of a failure of the plasma flood gun, since the measurement of the beam height is performed while ion implantation is occurring. Additionally, the use of the slope (rather than absolute numbers) means that the detection algorithm is unaffected by the maximum beam current being used. Further, since the beam height may be measured each time the workpiece is subject to one pass of the ion beam, this system allows continuous, real time detection of issues related to changes in the measured beam height. This may allow the ion implantation process to be paused quickly after an issue is identified, reducing the number of workpieces that may ultimately have to be discarded due to misprocessing. Further, by providing the data to a remote monitoring system, large amounts of data, from a plurality of ion implanters, may be gathered and analyzed to determine potential future failures and appropriate corrective actions.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment t for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of determining a height of an ion beam while the ion beam is being used to implant a workpiece, comprising:
directing the ion beam toward the workpiece;
scanning the workpiece in a first direction such that an entirety of the workpiece is implanted by the ion beam;
measuring a beam current as a function of scan position, using one or more current sensors disposed in a path of the ion beam, downstream from the workpiece as the workpiece is implanted by the ion beam;
determining a slope of the beam current with respect to scan position in the first direction; and
calculating the height of the ion beam based on the slope of the beam current.

2. The method of claim 1, wherein the beam current is measured and the height of the ion beam is calculated each time the workpiece is scanned in the first direction.

3. The method of claim 1, further comprising:
alerting an operator if an issue is detected, wherein an issue is detected when the height of the ion beam, as calculated, differs from an expected height.

4. The method of claim 1, further comprising:
automatically stopping an implant process if an issue is detected, wherein an issue is detected when the height of the ion beam, as calculated, differs from an expected height.

5. The method of claim 4, wherein the ion beam is generated by an ion implanter, and wherein the method further comprises:
automatically initiating a calibration process of the ion implanter after the implant process has been stopped to attempt to correct the issue.

6. The method of claim 1, further comprising:
alerting an operator if the height of the ion beam, as calculated, differs from an expected height by a first predetermined amount; and
automatically stopping an implant process if the height of the ion beam, as calculated, differs from the expected height by a second predetermined amount, greater than the first predetermined amount.

7. The method of claim 1, further comprising:
alerting an operator if a ratio of the height of the ion beam, as calculated, to an expected height is outside a first acceptable range; and
automatically stopping an implant process if the ratio is outside a second acceptable range, greater than the first acceptable range.

8. An ion implanter, comprising:
an ion source to generate an ion beam;
a process chamber, comprising:
a platen configured to move in a first direction such that an entirety of a workpiece disposed on the platen is implanted by the ion beam; and
one or more current sensors in a path of the ion beam downstream from the platen to measure beam current;
one or more beamline components to direct the ion beam toward the process chamber; and
a controller, to receive beam current measurements from the one or more current sensors and an associated scan position for each beam current measurement, wherein the controller is configured to calculate a height of the ion beam based on the beam current measurements and the associated scan positions.

9. The ion implanter of claim 8, wherein the beam current is measured and the height of the ion beam is calculated each time the workpiece is scanned in the first direction.

10. The ion implanter of claim 8, wherein the controller calculates a slope of the beam current as a function of scan position, and uses the slope to calculate the height of the ion beam.

11. The ion implanter of claim 8, wherein the controller alerts an operator if an issue is detected, wherein an issue is detected when the height of the ion beam, as calculated, differs from an expected height.

12. The ion implanter of claim 8, wherein the controller automatically stops an implant process if an issue is detected, wherein an issue is detected when the height of the ion beam, as calculated, differs from an expected height.

13. The ion implanter of claim 8, wherein the controller alerts an operator if the height of the ion beam, as calculated, differs from an expected height by a first predetermined amount; and
automatically stops an implant process if the height of the ion beam, as calculated, differs from the expected height by a second predetermined amount, greater than the first predetermined amount.

14. The ion implanter of claim 8, wherein the controller alerts an operator if a ratio of the height of the ion beam, as calculated, to an expected height is outside a first acceptable range; and
automatically stops an implant process if the ratio is outside a second acceptable range, greater than the first acceptable range.

15. A method of monitoring and controlling an operation of an ion implanter, comprising:
using the ion implanter to measure a beam current of an ion beam being directed toward a workpiece as a function of scan position as the workpiece is being implanted and scanned in a scanning direction;
transmitting data from the ion implanter to a remote monitoring system; and
using the data to provide an appropriate corrective action from the remote monitoring system to the ion implanter.

16. The method of claim 15, wherein the data transmitted from the ion implanter comprises measurements of beam current as a function of scan position; and wherein the remote monitoring system calculates beam height from the data.

17. The method of claim 16, wherein the remote monitoring system generates historical beam height trending from the beam height calculated from the data.

18. The method of claim 17, wherein the remote monitoring system also receives information regarding corrective actions that have previously been performed on the ion implanter.

19. The method of claim 18, wherein the remote monitoring system predicts future beam height changes and provides an appropriate corrective action.

20. The method of claim 19, wherein the remote monitoring system uses machine learning or artificial intelligence systems to provide the appropriate corrective action.
